(19) United States
(12) Patent Application Publication
(10) Pub. No.: US 2018/0130537 A1
(43) Pub. Date: May 10, 2018

(54) DATA STORAGE DEVICE AND OPERATING METHOD THEREOF

(71) Applicant: SK hynix Inc., Gyeonggi-do (KR)

(72) Inventors: Jin Woong KIM, Gyeonggi-do (KR); Se Hyun KIM, Seoul (KR); Kyu Min LEE, Seoul (KR)

(21) Appl. No.: 15/454,383

(22) Filed: Mar. 9, 2017

(30) Foreign Application Priority Data
Nov. 8, 2016 (KR) 10-2016-0148368

(51) Int. Cl. G11C 16/26; G06F 12/0802

(52) U.S. Cl. CPC G11C 16/26; G06F 2212/60; G06F 12/0802

(57) ABSTRACT

A data storage device includes a nonvolatile memory device; and a controller suitable for controlling the nonvolatile memory device, wherein the controller performs a first read retry voltage setting operation, performs a first read retry control operation, performs a second read retry voltage setting operation after an internal operation time of the nonvolatile memory device according to the first read retry control operation passes, and performs a second read retry control operation.

### CROSS-REFERENCES TO RELATED APPLICATION

The present application claims priority under 35 U.S.C. § 119(a) to Korean application number 10-2016-0148368, filed on Nov. 8, 2016, in the Korean Intellectual Property Office, which is incorporated herein by reference in its entirety.

### BACKGROUND

### 1. Technical Field

Various embodiments of the present invention relate generally to a data storage device which uses a nonvolatile memory device as a storage medium.

### 2. Related Art

Recently, the paradigm for the computer environment has been converted into ubiquitous computing so that computer systems can be used anytime and anywhere. Due to this, use of portable electronic devices such as mobile phones, digital cameras, and notebook computers has rapidly increased. In general, such portable electronic devices use a data storage device which uses a memory device. A data storage device is used to store data to be used in a portable electronic device.

A data storage device using a memory device provides advantages in that, since there is no mechanical driving part, stability and durability are excellent, an information access speed is high and power consumption is small. Data storage devices having such advantages include a universal serial bus (USB) memory device, memory cards having various interfaces, a universal flash storage (UFS) device, and a solid state drive (SSD).

### SUMMARY

Various embodiments of the present invention are directed to an improved data storage device capable of efficiently performing a read retry operation and an operating method thereof.

In an embodiment, a data storage device may include: a nonvolatile memory device; and a controller suitable for controlling the nonvolatile, memory device, wherein the controller performs a first read retry voltage setting operation, performs a first read retry control operation, performs a second read retry voltage setting operation after an internal operation time of the nonvolatile memory device according to the first read retry control operation passes, and performs a second read retry control operation.

In an embodiment, a method for operating a data storage device including a nonvolatile memory device and a controller which controls a read retry operation of the nonvolatile memory device may include: performing a first read retry voltage setting operation; performing a first read retry control operation; performing a second read retry voltage setting operation after an internal operation time of the nonvolatile memory device according to the first read retry control operation passes; and performing a second read retry control operation.

In an embodiment, a data storage device may include: a nonvolatile memory device, and a controller suitable for control the nonvolatile memory device to perform a read retry caching operation according to various levels of read retry voltages, wherein during the read retry caching operation the controller controls the nonvolatile memory device to cache a first data sensed according to a first read retry voltage while sensing a second data according to a second read retry voltage.

According to the embodiments, the read performance of a data storage device may be improved, and data reliability may be improved.

### BRIEF DESCRIPTION OF THE DRAWINGS

The above and other features and advantages of the present invention will become more apparent to those skilled in the art to which the present invention belongs by describing in detail various embodiments thereof with reference to the attached drawings in which:

FIG. 1 is a block diagram illustrating a data storage device, in accordance with an embodiment of the present invention.

FIG. 2 is a schematic diagram illustrating a software loaded on a working memory of FIG. 1.

FIG. 3 is a flow chart illustrating an operation of a read retry module of FIG. 2.

FIG. 4 is a threshold voltage distribution diagram illustrating a read retry voltage, ire accordance with an embodiment of he present invention.

FIG. 5 is a data sequence diagram illustrating an operation of the read retry module of FIG. 2.

FIG. 6 is a schematic diagram illustrating an operation of a nonvolatile memory device of FIG. 1.

FIG. 7 is a diagram illustrating a data processing system including a solid state drive (SSD), in accordance with an embodiment of the present invention.

FIG. 8 is a diagram illustrating an exemplary configuration of a controller shown in FIG. 7.

FIG. 9 is a diagram illustrating a data processing system including a data storage device, in accordance with another embodiment of the present invention.

FIG. 10 is a diagram illustrating a data processing system including a data storage device, in accordance with yet another embodiment of the present invention.

FIG. 11 is a diagram illustrating a network system including a data storage device, in accordance with an embodiment of the present invention.

FIG. 12 is a block diagram illustrating an exemplary configuration of a nonvolatile memory device included in a data storage device, in accordance with an embodiment of the present invention.

### DETAILED DESCRIPTION

In the present invention, advantages, features and methods for achieving them will become more apparent after reading of the following exemplary embodiments taken in conjunction with the drawings. The present invention may, however, be embodied in different forms and should not be construed as being limited only to the embodiments set forth herein. Rather, these embodiments are provided to describe the present invention in detail to the extent that a person skilled in the art to which the invention pertains can easily enforce the technical concept of the present invention.

It is to be understood herein that embodiments of the present invention are not limited to the particulars shown in the drawings and that the drawings are not necessarily to scale and in some instances proportions may have been exaggerated in order to more clearly depict certain features of the invention. While particular terminology is used herein, it is to be appreciated that the terminology used herein is for the purpose of describing particular embodiments only and is not intended to limit the scope of the present invention.

As used herein, the term “and/or” includes any and all combinations of one or more of the associated listed items. It will be understood that when an element is referred to as being “on,” “connected to” or “coupled to” another element, it may be directly on, connected or coupled to the other element or intervening elements may be present. As used herein, a singular form is intended to include plural forms as well, unless the context clearly indicates otherwise. It will be further understood that the terms “includes/comprises” and/or “including/comprising,” when used in this specification, specify the presence of at least one stated feature, step, operation, and/or element, but do not preclude the presence or addition of one or more other features, steps, operations, and/or elements thereof.

Hereinafter, a data storage device and an operating method thereof will be described below with reference to the accompanying drawings through various examples of embodiments.

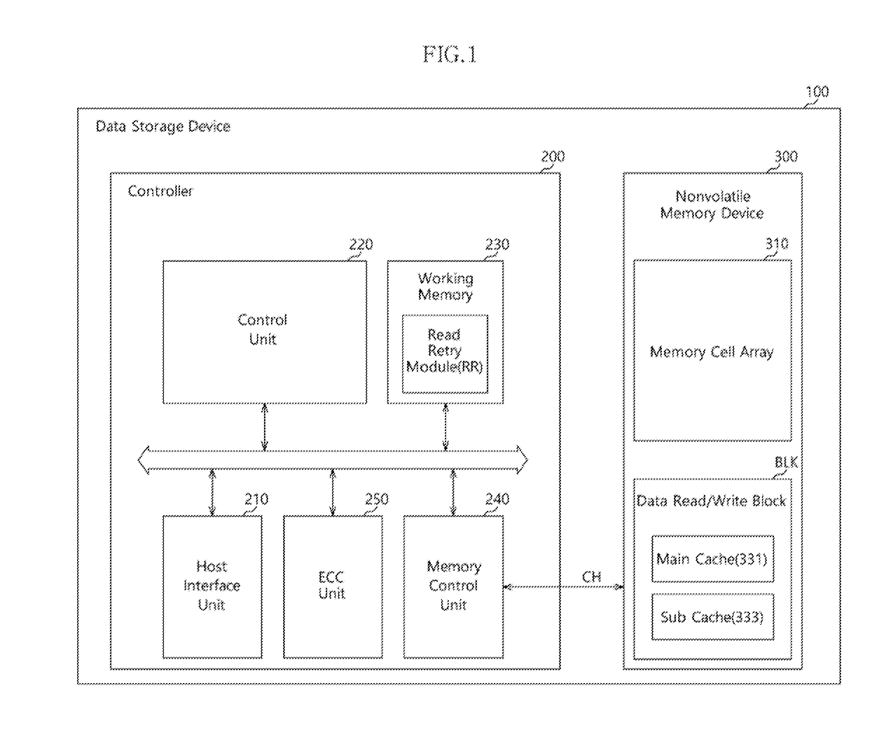

FIG. 1 is a block diagram illustrating a data storage device 100, in accordance with an embodiment of the present invention. The data storage device 100 may store data to be accessed by a host device (not shown). The host device may be an electronic device such as a mobile phone, an MP3 player, a laptop computer, a desktop computer, a game player, a TV, an in-vehicle infotainment system, and so forth. The data storage device 100 may also be referred to as a memory system.

The data storage device 100 may be configured as any one of various kinds of storage devices according to the protocol of an interface which is electrically coupled with the host device. For example, the data storage device 100 may be configured as any one of various kinds of storage devices such as a solid state drive, a multimedia card in the form of an MMC, an eMMC, an RS-MMC and a micro-MMC, a secure digital card in the form of an SD, a mini-SD and a micro-SD, a universal serial bus (USB) storage device, a universal flash storage (UFS) device, a personal computer memory card international association (PCMCIA) card type storage device, a peripheral component interconnection (PCI) card type storage device, a PCI express (PCI-E) card type storage device, a compact flash (CF) card, a smart media card, a memory stick, and so forth.

The data storage device 100 may be manufactured as any one among various kinds of package types. For example, the data storage device 100 may be manufactured as any one of various kinds of package types such as a package-on-package (POP), a system-in-package (SIP), a system-on-chip (SOC), a multi-chip package (MCP), a chip-on-board (COB), a wafer-level fabricated package (WFP) and a wafer-level stack package (WSP).

The data storage device 100 may include a controller 200 and a nonvolatile memory device 300 operatively coupled to one another.

The controller 200 may include a host interface unit 210, a control unit 220, a working memory 230, a memory control unit 240, and an ECC (error correction code) unit 250 operatively coupled via an internal bus.

The host interface unit 210 may interface the host device and the data storage device 100. Any suitable host interface unit may be used. For example, the host interface unit 210 may communicate with the host device by using a host interface, that is, any one among a plurality of well-known, standard transmission protocols such as a universal serial bus (USB), a universal flash storage (UFS), a multimedia card (MMC), a parallel advanced technology attachment (PATA), a serial advanced technology attachment (SATA), a small computer system interface (SCSI), a serial attached SCSI (SAS), peripheral component interconnection (PCI) and a PCI express (PCI-E) protocol.

The control unit 220 may control the general operations of the controller 200. The control unit 220 may drive an instruction or an algorithm of a code type, that is, a software which may be loaded on the working memory 230, for controlling the operations of the internal function blocks of the controller 200. In an embodiment, the control unit 220 may be a micro control unit (MCU) also referred to as a microcontroller or a microprocessor or a system on a chip (SOC).. In another embodiment, the control unit 220 may be a central processing unit (CPU) of a computer system.

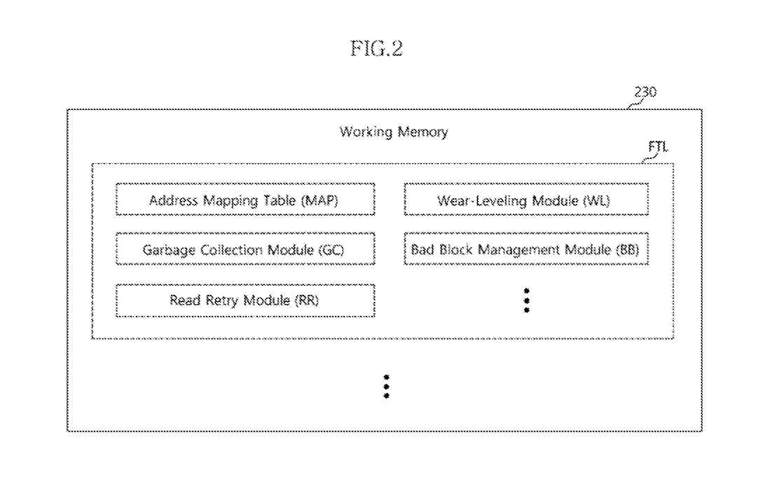

The working memory 230 may store a software to be driven by the control unit 220. Also, the working memory 230 may store the data for driving the software. The software loaded on the working memory 230, such as a read retry module RR, will be described in detail with reference to FIG. 2. The working memory 230 may be implemented with a random access memory such as a dynamic random access memory (DRAM) or a static random access memory (SRAM).

The memory control unit 240 may control the nonvolatile memory device 300 according to control of the control unit 220. The memory control unit 240 may also be referred to as a memory interface unit. The memory control unit 240 may provide control signals to the nonvolatile memory device 300. The control signals may include a command, an address, a control signal and so forth for controlling the nonvolatile memory device 300. The memory control unit 240 may provide data to the nonvolatile memory device 300 or may receive the data read out from the nonvolatile memory device 300.

The error correction code (ECC) unit 250 may detect whether an error is included in the data read out from the nonvolatile memory device 300 and correct the error included in the data. To this end, the error correction code (EEC) unit 250 may generate an error correction code for data to he stored in the nonvolatile memory device 300. The error correction code (ECC) unit 250 may detect and correct an error of the data read out from the nonvolatile memory device 300, based on the error correction code.

The nonvolatile memory device 300 may be coupled with the controller 200 through a channel CH. The channel CH may be one or more signal lines capable of transmitting a command, an address, control signals and data. The nonvolatile memory device 300 may be used as the storage medium of the data storage device 100.

The nonvolatile memory device 300 may be configured by any one of various nonvolatile memory devices such as a NAND flash memory device, a NOR flash memory device, a ferroelectric random access memory (FRAM) using a ferroelectric capacitor, a magnetic random access memory (MRAM) using a tunneling magneto-resistive (TMR) layer, a phase change random access memory (PCRAM) using a chalcogenide alloy, and a resistive random access memory (RERAM) using a transition metal oxide. The ferroelectric random access memory (FRAM), the magnetic random access memory (MRAM), the phase change random access memory (PCRAM) and the resistive random access memory (RERAM) are examples of nonvolatile random access memory devices capable of random access to memory cells. In an embodiment, the nonvolatile memory device 300 may be configured by a combination of a NAND flash memory device and any one of the above-described various nonvolatile random access memory devices. In the following descriptions, an embodiment which the nonvolatile memory device 300 is configured by a flash memory device will be described as an example.

The nonvolatile memory device 300 may include a memory cell array 310 and a data read/write block 330.

The memory cell array 310 may be divided in a plurality of pages. A page may be defined as a set of memory cells that can be read or programmed simultaneously. The memory cell array 310 may also be divided in a plurality of blocks. A block may include a plurality of pages and may be defined as a set of memory cells that can be erased simultaneously.

The data read/write block 330 may include a main cache 331 and a sub cache 333 which may store, by the unit of a page, data to be stored in the memory cell array 310 or read out (or sensed) from the memory cell array 310.

FIG. 2 is a schematic diagram illustrating a software loaded on the working memory 230. As described above, the nonvolatile memory device 300 may be erased by the unit of a block, and may be read or programmed by the unit of a page. Further, since it is not possible to overwrite the nonvolatile memory device 300, an erase operation should be performed to memory cells, which are storing data, before a program operation for new data to the memory cells.

The control unit 220 may drive the software which is called a flash translation layer FTL to control such characteristics of the nonvolatile memory device 300 and render device compatibility to the host device. Through driving of such a flash translation layer FTL, the data storage device 100 may be recognized as a general data storage device such as a hard disk, by the host device.

The flash transaction layer FTL may be loaded on the working memory 230 and may include a plurality of modules for performing various functions and metadata required for driving of the modules. For example, the flash translation layer FTL may include an address mapping table MAP, a wear-leveling module WL, a garbage collection module GC, a bad block management module BB, and the read retry module RR.

In operation, the host device may access the data storage device 100, for example, may request a read operation or a write operation. The host device may provide a logical address to the data storage device 100. The flash translation layer FTL may translate the provided logical address into a physical address of the nonvolatile memory device 300, and perform the requested read or program operation by referring to the converted physical address. For such an address translation operation, address translation data, that is, the address mapping table MAP may be included in the flash translation layer FTL.

The wear-leveling module WL may manage degrees of wear for the pages or blocks of the nonvolatile memory device 300. Memory cells of the nonvolatile memory device 300 may be aged by program and erase operations. Aged memory cells, that is, worn-out memory cells may cause fails. The wear-leveling module WL may manage the program-erase counts of respective blocks in such a way to be leveled, to prevent uneven wearing out of the blocks.

The garbage collection module GC may manage blocks where fragmented data are stored. As described above, the nonvolatile memory device 300 is impossible to perform an overwrite operation, and the unit of erase may be larger than the unit of program. For this reason, the nonvolatile memory device 300 may need an operation of collecting valid data dispersed at physically different positions to one place, when a storage space reaches a limit. The garbage collection module GC may perform an operation of collecting valid data fragmented due to performing of a plurality of program operations and a plurality of erase operations, to a collection area, thereby securing a usable memory area.

The bad block management module BB may manage a block in which a fail has occurred, among the blocks of the nonvolatile memory device 300. As described above, a fail may occur in a worn-out memory cell. Data stored in a failed memory cell may not be read out normally. Moreover, data may not be stored normally in a failed memory cell. The bad block management module BB may manage a block including a failed memory cell, in a way that the failed memory cell is not used.

For various reasons, an error may be included in the data stored in the nonvolatile memory device 300. An error included in data may be detected and corrected by the ECC unit 250. However, in the case where an error included in data may not be corrected by the ECC unit 250, a read fail may occur. The read retry module RR may control the nonvolatile memory device 300 such that a read retry operation is performed to a memory cell in which a read fail has occurred.

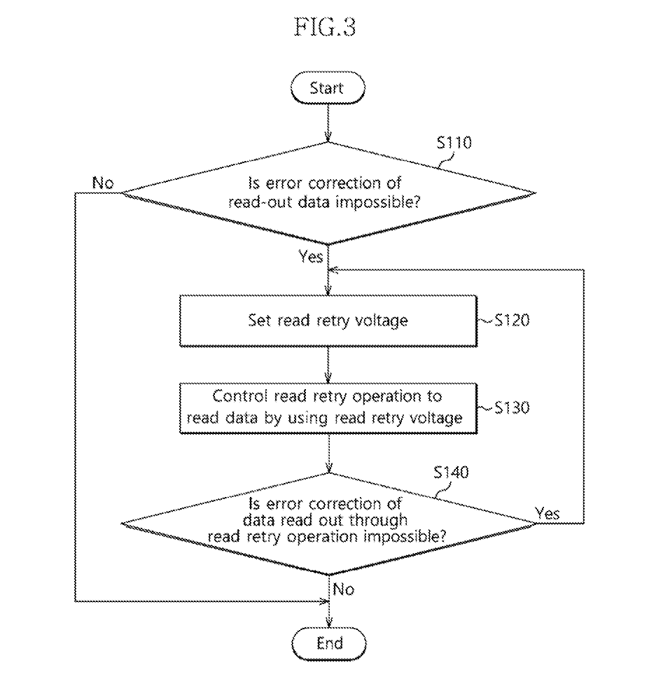

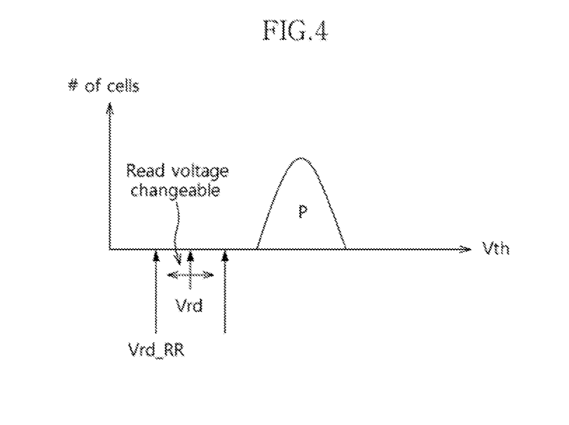

FIG. 3 is a flow chart illustrating an operation of the read retry module RR, n accordance with an embodiment of the present invention. FIG. 4 is a threshold voltage distribution diagram illustrating a read retry voltage in accordance with an embodiment of the present invention. The read retry module RR is a software module driven by the control unit 220, hence, descriptions, herein will be made from the viewpoint of the control unit 220 with reference to FIGS. 3 and 4.

At step S110, the control unit 220 may determine whether an error of the data read out from the nonvolatile memory device 300 according to an original read voltage Vrd is not possible. Whether the error cannot be corrected may be determined through the error detection and correction operations of the ECC unit 250. In the case where the error correction is possible, the control unit 220 may end the process without performing a read retry operation. In the case where the determination in step S110 is that the error correction is impossible (YES in S110), the control unit 220 may perform the following process.

At step S120, the control unit 220 may set a read retry voltage Vrd_RR. As shown in FIG. 4 the control unit 220 may set the read retry voltage Vrd_RR different from the original read voltage Vrd for determining a program state P. The read retry voltage Vrd_RR may be a voltage lower or higher than the original read voltage Vrd.

At step S130 the control unit 220 may control a read retry operation to read data by using the read retry voltage Vrd_RR. For instance, the control unit 220 may provide the read retry voltage Vrd_RR to the nonvolatile memory device 300 through a read retry voltage setting command for setting the read retry voltage Vrd_RR. Also, the control unit 220 may provide the nonvolatile memory device 300 with a read retry command for instructing the read retry operation and a read retry address of a target memory cell for the read retry operation.

According to the read retry voltage setting command, the read retry command and the read retry address, the nonvolatile memory device 300 may apply the read retry voltage Vrd_RR to the word line of the memory cell corresponding to the read retry address, and provide read-out data to the controller 200.

At step S140, the control unit 220 may determine whether an error of the data read out by using the read retry voltage Vrd_RR is not possible. Whether the error can be corrected may be determined through the error detection and correction operations of the ECC unit 250. In the case where the error can be corrected, the control unit 220 may end the read retry operation. In the case where the error cannot be corrected, the control unit 220 may repeat steps S120 to S140 such that a read operation is performed again by changing the read retry voltage Vrd_RR.

For instance, the control unit 220 may repeat steps S120 to S140 within a predetermined count until a read fail does not occur,

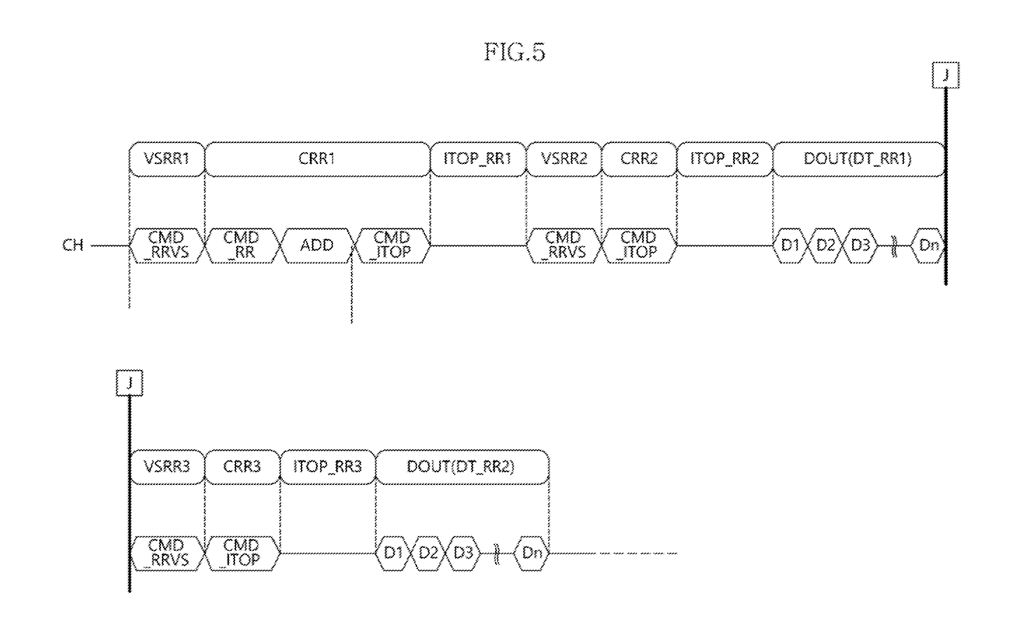

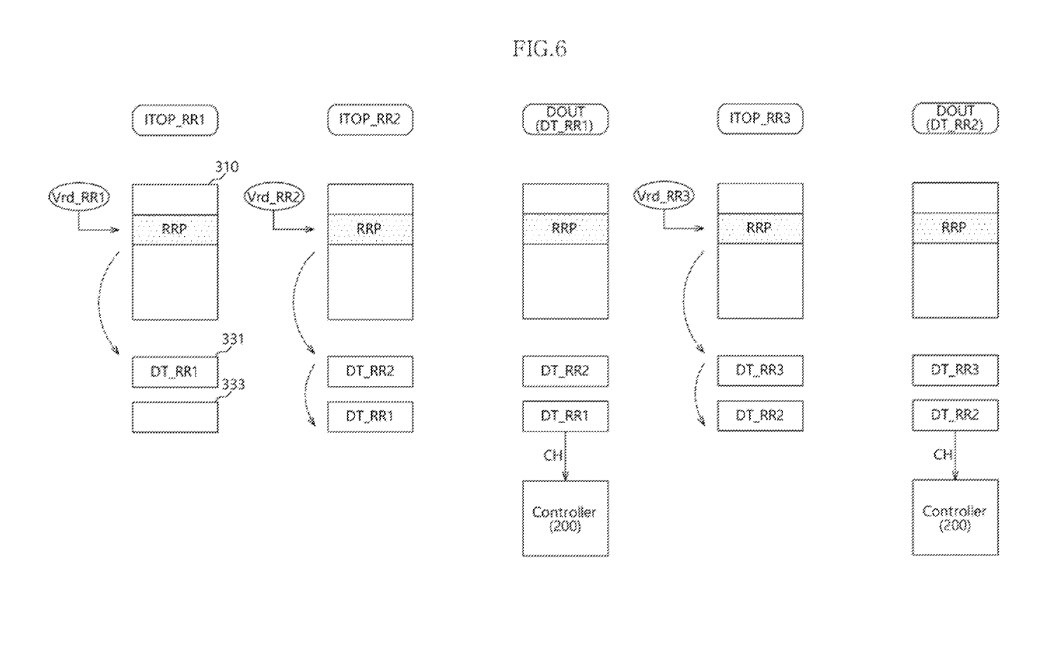

FIG. 5 is a data sequence diagram illustrating the operation of the read retry module RR. FIG. 6 is a schematic diagram illustrating the operation of the nonvolatile memory device 300. For the sake of convenience in explanation, an example in which a read retry operation is performed three times is illustrated in FIG. 5. Since the read retry module RR is a software module driven by the control unit 220, descriptions will be made from the viewpoint of the control unit 220 with reference to FIG. 5.

The control unit 220 may perform a first read retry voltage setting operation VSRR1. For example, the control unit 220 may provide a first read retry voltage Vrd_RR1 to the nonvolatile memory device 300 through a read retry voltage setting command CMD_RRVS.

The control unit 220 may perform a first read retry control operation CRR1. For example, the control unit: 220 may provide the nonvolatile memory device 300 with a read retry command CMD_RR, a read retry address ADD and a command CMD_ITOP instructing to start an internal operation.

As shown in FIG. 6, according to the command CMD_ITOP instructing to start an internal operation, the nonvolatile memory device 300 may perform a first internal operation ITOP_RR1 of applying the first read retry voltage Vrd_RR1 to the memory cells of a page RRP corresponding to the read retry address ADD, sensing the memory cells and storing sensed data DT_RR1 in the main cache 331. An internal operation time of the nonvolatile memory device is a sensing time i.e., the time required for the nonvolatile memory device to complete sensing of data from memory cells to the main cache 331.

If the first internal operation ITOP_RR1 is ended (that is, after the internal operation time of the nonvolatile memory device 300 passes), the control unit 220 may perform a second read retry voltage setting operation VSRR2. For example, the control unit 220 may provide a second read retry voltage Vrd_RR2 to the nonvolatile memory device 300 through a read retry voltage setting command CMD_RRVS.

The control unit 220 may perform a second read retry control operation CRR2. For example, the control unit 220 may provide the nonvolatile memory device 300 with the command CMD_{—} TOP instructing to start an internal operation.

As shown in FIG. 6, according to the command CMD_ITOP instructing to start an internal operation, the nonvolatile memory device 300 may perform a second internal operation ITOP_RR2 of applying the second read retry voltage Vrd_RR2 to the memory cells of the page RRP corresponding to the read retry address ADD, sensing the memory cells and storing sensed data DT_RR2 in the main cache 331. At this time, the data DT_RR1 sensed by using the first read retry voltage Vrd_RR1 may be dumped or moved to the sub cache 333 from the main cache 331

If the second internal operation ITOP_RR2 is ended (that is, after the internal operation time of the nonvolatile memory device 300 passes), the control unit 220 may perform a data output control operation DOUT. For example, the control unit 220 may provide a read control signal or a data strobe signal to the nonvolatile memory device 300 such that the data DT_RR1 sensed by using the first read retry voltage Vrd_RR1 is outputted.

As shown in FIG. 6, according to the read control signal or the data strobe signal, the nonvolatile memory device 300 may provide the controller 200 through the channel CH with the data DT_RR1 stored in the sub cache 333.

If the data output from the nonvolatile memory device 300 is completed, the control unit 220 may perform a third read retry voltage setting operation VSRR3. For example, the control unit 220 may provide a third read retry voltage Vrd_RR3 to the nonvolatile memory device 300 through a read retry voltage setting command CMD_RRVS.

The control unit 220 may perform a third read retry control operation CRR3. For example, the control unit 220 may provide the nonvolatile memory device 300 with the command CMD_ITOP instructing to start an internal operation.

As shown in FIG. 6, according to the command CMD_ITOP instructing to start an internal operation, the nonvolatile memory device 300 may perform a third internal operation ITOP_RR3 of applying the third read retry voltage Vrd_RR3 to the memory cells of the page RRP corresponding to the read retry address ADD, sensing the memory cells and storing sensed data DT_RR3 in the main cache 331. At this time, the data DT_RR2 sensed by using the second read retry voltage Vrd_RR2 may be dumped or moved to the sub cache 333 from the main cache 331.

If the third internal operation ITOP_RR3 is ended (that is, after the internal operation time of the nonvolatile memory device 300 passes), the control unit 220 may perform a data output control operation DOUT. For example, the control unit 220 may provide the read control signal or the data strobe signal to the nonvolatile memory device 300 such that the data DT_RR2 sensed by using the second read retry voltage Vrd_RR2 is outputted.

As shown in FIG. 6, according to the read control signal or the data strobe signal, the nonvolatile memory device 300 may provide the controller 200 through the channel CH with the data DT_RR2 stored in the sub cache 333.

In the description of FIG. 5, it is illustrated that the third read retry voltage setting operation VSSR3, the third read retry control operation CRR3 and the data output control operation DOUT are performed in the case where the error of the data DT_RR1 sensed by using the first read retry voltage Vrd_RR1 cannot be corrected. If the error of the data DT_RR1 sensed by using the first read retry voltage Vrd_RR1 can be corrected, the control unit 220 may omit the third read retry voltage setting operation VSSR3, the third read retry control operation CRR3 and the data output control operation DOUT.

As described above with reference to FIGS. 5 and 6 the control unit 220 may perform a read retry operation by using a caching scheme. That is to say, the control unit 220 may perform a read retry caching operation in which the data is sensed according to currently set read retry voltage before the data sensed according to previously set read retry voltage is outputted to the controller 200. According to the read retry caching operation, the data sensed according to previously set read retry voltage is cached while the data is sensed according to currently set read retry voltage. Referring to FIG. 6, the data DT_RR1 sensed according to the first read retry voltage Vrd_RR1 may be cached into the sub cache 333 while the data DT_RR2 is sensed according to the second read retry voltage Vrd_RR2. Further, the data DT_RR2 sensed according to the second read retry voltage Vrd_RR2 may be cached into the sub cache 333 while the data DT_RR3 is sensed according to the third read retry voltage Vrd_RR3. As the read retry caching operation is performed, a time required for the read retry operation may be shortened. If the error of the data sensed according to previously set read retry voltage can be corrected, an operation of outputting the data sensed according to currently set read retry voltage may be omitted, and the read retry operation may be ended. Referring to FIG. 6, when the error of the data DT_RR1 sensed according to the first read retry voltage Vrd_RR1 can be corrected, the control unit 220 may omit the data output control operation DOUT for the data DT_RR3 sensed according to the third read retry voltage Vrd_RR3.

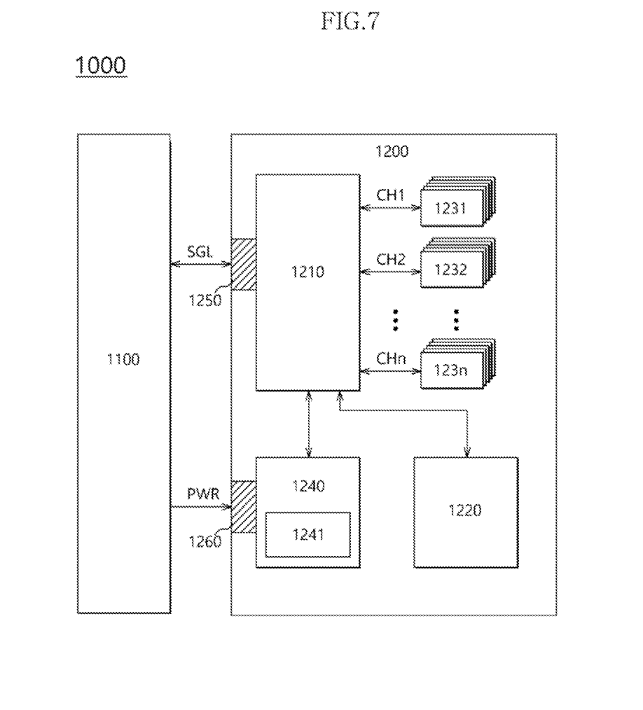

FIG. 7 is a diagram illustrating a data processing system including a solid state drive (SSD) in accordance with an embodiment of the present invention. Referring to FIG. 7, a data processing system 1000 may include, a host device 1100 and a solid state drive (SSD) 1200.

The SSD 1200 may include a controller 1210, a buffer memory device 1220, nonvolatile memory devices 1231 to 123n, a power supply 1240, a signal connector 1250, and a power connector 1260.

The controller 1210 may control general operations of the SSD 1200.

The buffer memory device 1220 may temporarily store data to be stored in the nonvolatile memory devices 1231 to 123n. Further, the buffer memory device 1220 may temporarily store the data read out from the nonvolatile memory devices 1231 to 123n. The data temporarily stored in the buffer memory device 1220 may be transmitted to the host device 1100 or the nonvolatile memory devices 1231 to 123n according to control of the controller 1210.

The nonvolatile memory devices 1231 to 123n may be used as storage media of the SSD 1200. The nonvolatile memory devices 1231 to 123n may be coupled with the controller 1210 through a plurality of channels CH1 to CHn, respectively. One or more nonvolatile memory devices may be coupled to one channel. The nonvolatile memory devices coupled to each channel may be coupled to the same signal bus and data bus.

The power supply 1240 may provide power PWR inputted through the power connector 1260, to the inside of the SSD 1200. The power supply 1240 may include an auxiliary power supply 1241. The auxiliary power supply 1241 may supply power to allow the SSD 1200 to be normally terminated when a sudden power-off occurs. The auxiliary power supply 1241 may include large capacitance capacitors capable of charging power PWR.

The controller 1210 may exchange a signal SGL with the host device 1100 through the signal connector 1250. The signal SGL may include a command, an address, data, and so forth. The signal connector 1250 may be constructed by various types of connectors depending on an interface scheme between the host device 1100 and the SSD 1200.

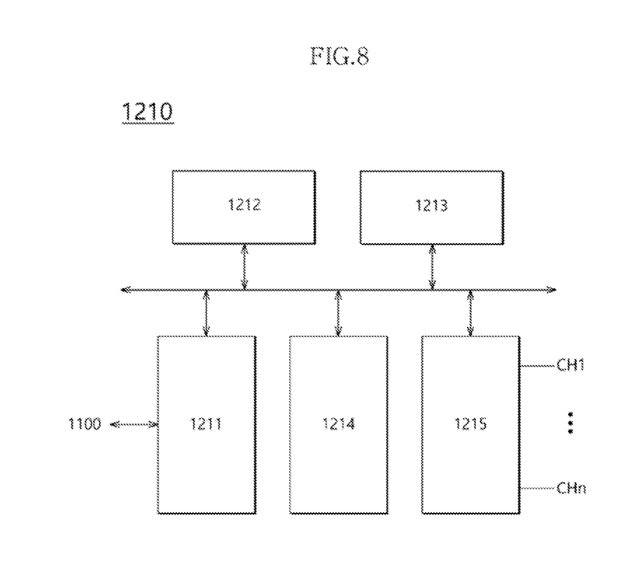

FIG. 8 is a diagram illustrating the controller shown in FIG. 7. Referring to FIG. 8, the controller 1210 may include a host interface unit 1211, a control unit 1212, a random access memory 1213, an error correction code (ECC) unit 1214, and a memory interface unit 1215.

The host interface unit 1211 may interface the host device 1100 and the SSD 1200 according to the protocol of the host device 1100. For example, the host interface unit 1211 may communicate with the host device 1100 through any one of secure digital, universal serial bus (USB), multimedia card (MMC), embedded MMC (eMMC), personal computer memory card international association (PCMCIA), parallel advanced technology attachment (PATA), serial advanced technology attachment (SATA), small computer system interface (SCSI), serial attached SCSI (SAS), peripheral component interconnection (PCI), PCI express (PCI -E) and universal flash storage (UFS) protocols. In addition, the host interface unit 1211 may perform a disk emulating function for supporting the host device 1100 to recognize the SSD 1200 as a general purpose data storage device, for example, a hard disk drive (HDD).

The control unit 1212 may analyze and process the signal SGL inputted from the host device 1100. The control unit 1212 may control operations of internal function blocks according to a firmware or a software for driving the SSD 1200. The random access memory 1213 may be used as a working memory for driving such a firmware or software.

The error correction code (ECC) unit 1214 may generate the parity data of data to be transmitted to the nonvolatile memory devices 1231 to 123n. The generated parity data may be stored together with the data in the nonvolatile memory devices 1231 to 123n. The error correction code (ECC) unit 1214 may detect an error of the data read out from the nonvolatile memory devices 1231 to 123n, based on parity data. If a detected error is within a correctable range, the error correction code (ECC) unit 1214 may correct the detected error.

The memory interface unit 1215 may provide control signals such as commands and addresses to the nonvolatile memory devices 1231 to 123n, according to control of the control unit 1212. Moreover, the memory interface unit 1215 may exchange data with the nonvolatile memory devices 1231 to 123n, according to control of the control unit 1212. For example, the memory interface unit 1215 may provide the data stored in the buffer memory device 1220, to the nonvolatile memory devices 1231 to 123n, or provide the data read out from the nonvolatile memory devices 1231 to 123n to the buffer memory device 1220.

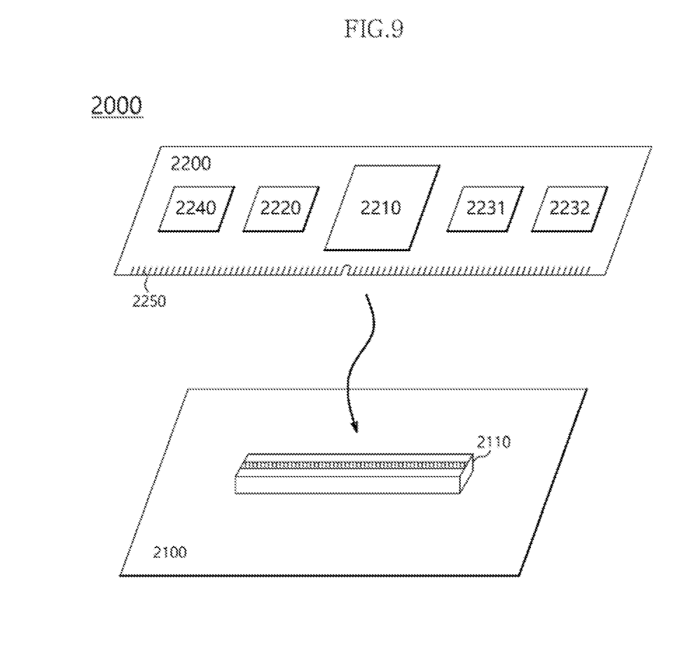

FIG. 9 is a diagram illustrating a data processing system including a data storage device in accordance with an embodiment of the present invention. Referring to FIG. 9, a data processing system 2000 may include a host device 2100 and a data storage device 2200.

The host device 2100 may be constructed in the form of a board such as a printed circuit board. Although not shown, the host device 3100 may include internal function blocks for performing the function of a host device.

The host device 2100 may include a connection terminal 2110 such as a socket, a slot or a connector. The data storage device 2200 may be mounted to the connection terminal 2110.

The data storage device 2200 may be constructed in the form of a board such as a printed circuit board. The data storage device 2200 may be referred to as a memory module or a memory card. The data storage device 2200 may include a controller 2210, a buffer memory device 2220, nonvolatile memory devices 2231 and 2232, a power management integrated circuit (PMIC) 2240, and a is connection terminal 2250.

The controller 2210 may control general operations of the data storage device 2200. The controller 2210 may be configured in the same manner as the controller 1210 shown in FIG. 7.

The buffer memory device 2220 may temporarily store data to be stored in the nonvolatile memory devices 2231 and 2232. Further, the buffer memory device 2220 may temporarily store the data read out from the nonvolatile memory devices 2231 and 2232. The data temporarily stored in the buffer memory device 2220 may be transmitted to the host device 2100 or the nonvolatile memory devices 2231 and 2232 according to control of the controller 2210.

The nonvolatile memory devices 2231 and 2232 may be used as storage media of the data storage device 2200.

The PMIC 2240 may provide the power inputted through the connection terminal 2250, to the inside of the data storage device 2200. The PMIC 2240 may manage the power of the data storage device 2200 according to control of the controller 2210.

The connection terminal 2250 may be coupled to the connection terminal 2110 of the host device 2100. Through the connection terminal 2250, signals such as commands, addresses, data and so forth and power may be transferred between the host device 2100 and the data storage device 2200. The connection terminal 2250 may be constructed into various types depending on an interface scheme between the host device 2100 and the data storage device 2200. The connection terminal 2250 may be disposed on any one side of the data storage device 2200.

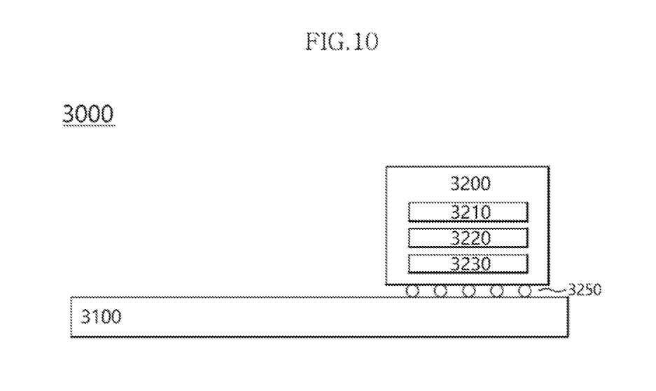

FIG. 10 is a diagram illustrating a data processing system including a data storage device in accordance with an embodiment of the present invention. Referring to FIG. 10, a data processing system 3000 may include a host device 3100 and a data storage device 3200.

The host device 3100 may be constructed in the form of a board such as a printed circuit board. Although not shown, the host device 3100 may include internal function blocks for performing the function of a host device.

The data storage device 3200 may be constructed in the form of a surface-mounting type package. The data storage device 3200 may be mounted to the host device 3100 through solder balls 3250. The data storage device 3200 may include a controller 3210, a buffer memory device 3220, and a nonvolatile memory device 3230.

The controller 3210 may control general operations of the data storage device 3200. The controller 3210 may be configured in the same manner as the controller 1210 shown in FIG. 7.

The buffer memory device 3220 may temporarily store data to be stored in the nonvolatile memory device 3230. Further, the buffer memory device 3220 may temporarily store the data read out from the nonvolatile memory device 3230. The data temporarily stored in the buffer memory device 3220 may be transmitted to the host device 3100 or the nonvolatile memory device 3230 according to control of the controller 3210.

The nonvolatile memory device 3230 may be used as the storage medium of the data storage device 3200.

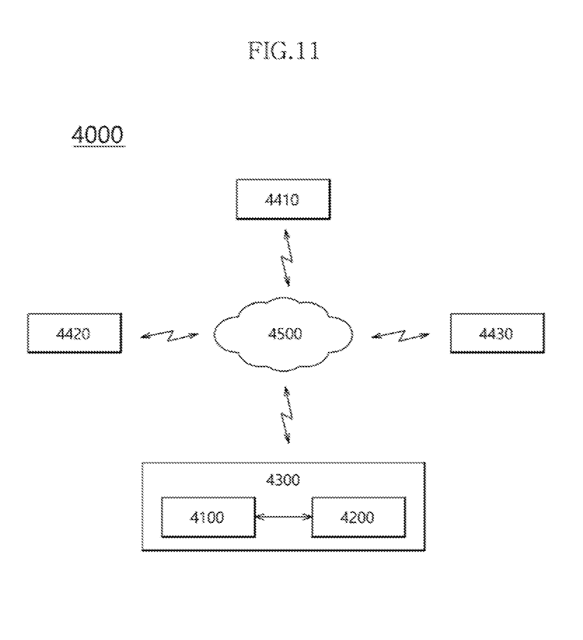

FIG. 11 is a diagram illustrating a network system including a data storage device in accordance with an embodiment of the present invention. Referring to FIG. 11, a network system 4000 may include a server system 4300 and a plurality of client systems 4410 to 4430 which are coupled through a network 4500.

The server system 4300 may service data in response to requests from the plurality of client systems 4410 to 4430. For example, the server system 4300 may store the data provided from the plurality of client systems 4410 to 4430. For another example, the server system 4300 may provide data to the plurality of client systems 4410 to 4430.

The server system 4300 may include a host device 4100 and a data storage device 4200. The data storage device 4200 may be constructed by the data storage device 100 shown in FIG. 1, the data storage device 1200 shown in FIG. 7, the data storage device 2200 shown in FIG. 9 or the data storage device 3200 shown in FIG. 10.

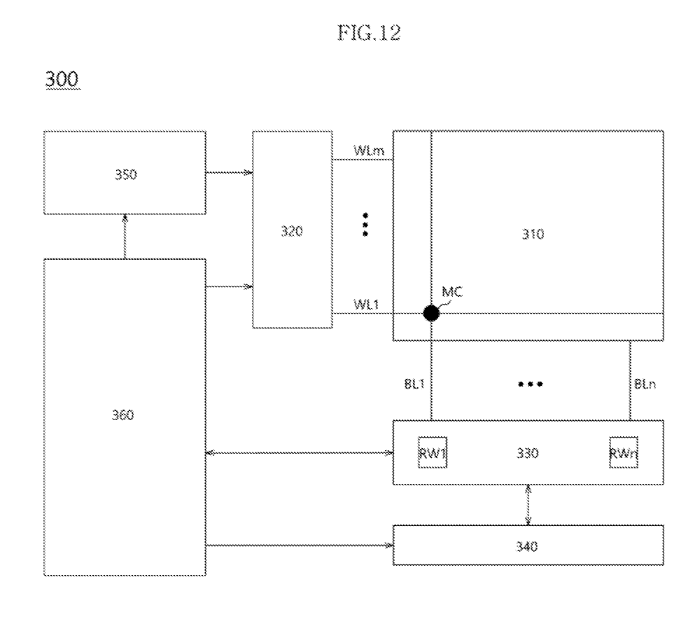

FIG. 12 is a block diagram illustrating a nonvolatile memory device included in a data storage device in accordance with an embodiment of the present invention. Referring to FIG. 12, the nonvolatile memory device 300 may include a memory cell array 310, a row decoder 320, a column decoder 330, a data read/write block 340, a voltage generator 350, and a control logic 360.

The memory cell array 310 may include memory cells MC which are arranged at areas where word lines WL1 to WLm and bit lines BL1 to BLn intersect with each other.

The row decoder 320 may be coupled with the memory cell array 310 through the word lines WL1 to WLm. The row decoder 320 may operate according to control of the control logic 360. The row decoder 320 may decode an address provided from an external device (not shown). The row decoder 320 may select and drive the word lines WL1 to WLm, based on a decoding result. For instance, the row decoder 320 may provide a word line voltage provided from the voltage generator 350, to the word lines WL1 to WLm.

The data read/write block 340 may be coupled with the memory cell array 310 through the bit lines BL1 to BLn. The data read/write block 340 may include read/write circuits RW1 to RWn respectively corresponding to the bit lines BL1 to BLn. The data read/write block 340 may operate according to control of the control logic 360. The data read/write block 340 may operate as a write driver or a sense amplifier according to an operation mode. For example, the data read/write block 340 may operate as a write driver which stores data provided from the external device, in the memory cell array 310 in a write operation. For another example, the data read/write block 340 may operate as a sense amplifier which reads out data from the memory cell array 310 in a read operation.

The column decoder 330 may operate according to control of the control logic 360. The column decoder 330 may decode an address provided from the external device. The column decoder 330 may couple the read/write circuits RW1 to RWn of the data read/write block 340 respectively corresponding to the bit lines BL1 to BLn with data input/output lines (or data input/output buffers), based on a decoding result.

The voltage generator 350 may generate voltages to be used in internal operations of the semiconductor memory device 300. The voltages generated by the voltage generator 350 may be applied to the memory cells of the memory cell array 310. For example, a program voltage generated in a program operation may be applied to a word line of memory cells for which the program operation is to be performed. For another example, an erase voltage generated in an erase operation may be applied to a well area of memory cells for which the erase operation is to be performed. For still another example, a read voltage generated in a read operation may be applied to a word line of memory cells for which the read operation is to be performed.

The control logic 360 may control general operations of the semiconductor memory device 300, based on control signals provided from the external device. For example, the control logic 360 may control operations of the semiconductor memory device 300 such as read, write and erase operations of the semiconductor memory device 300.

While various embodiments have been described above, it will be understood to those skilled in the art that the embodiments described are examples only. Accordingly, the data storage device and the operating method thereof described herein should not be limited based on the described embodiments. Various other embodiments and/or variations thereof may be envisaged by those skilled in the art to which the present invention pertains without departing from the scope of the present invention as defined by the following claims.

What is claimed is:

1. A data storage device comprising:
a nonvolatile memory device; and
a controller suitable for controlling the nonvolatile memory device,
wherein the controller performs a first read retry voltage setting operation, performs a first read retry control operation, performs a second read retry voltage setting operation after an internal operation time of the nonvolatile memory device according to the first read retry control operation passes, and performs a second read retry control operation.

2. The data storage device according to claim 1, wherein the controller further performs a first data output control operation of controlling the nonvolatile memory device to output data sensed according to the first read retry control operation after an internal operation time of the nonvolatile memory device according to the second read retry control operation passes.

3. The data storage device according to claim 2, wherein the controller further performs a second data output control operation of controlling the nonvolatile memory device to output data sensed according to the second read retry control operation when an error of the data sensed according to the first read retry control operation is uncorrectable, and omits the second data output control operation of controlling the nonvolatile memory device to output the data sensed according to the second read retry control operation when the error of the data sensed according to the first read retry control operation is correctable.

4. The data storage device according to claim 2, wherein the controller provides a read control signal or a data strobe signal to the nonvolatile memory device during the first data output control operation.

5. The data storage device according to claim 1, wherein the controller performs the first read retry voltage setting, operation of providing a first read retry voltage to the nonvolatile memory device, through a read retry voltage setting command.

6. The data storage device according to claim 5, wherein the controller performs the first read retry control operation of providing a read retry command, a read retry address and a command instructing to start an internal operation by using the first read retry voltage, to the nonvolatile memory device.

7. The data storage device according to claim 6, wherein the nonvolatile memory device applies the first read retry voltage to memory cells corresponding to the read retry address, according to the command instructing to start the internal operation, and senses the memory cells.

8. The data storage device according to claim 1, wherein the controller performs the second read retry voltage setting operation of providing a second read retry voltage to the nonvolatile memory device, through a read retry voltage setting command.

9. The data storage device according to claim 8, wherein the controller performs the second read retry control operation of providing a command instructing to start an internal operation by using the second read retry voltage, to the nonvolatile memory device.

10. The data storage device according, to claim 1,
wherein the nonvolatile memory device includes a memory cell array and a data read block which senses data from the memory cell array,
wherein the data read block includes a main cache and a sub cache which store sensed data,
wherein the data sensed according to the first read retry control operation is stored in the main cache, and
wherein, when the data sensed according to the second read retry control operation is stored in the main cache, the data sensed according to the first read retry control operation is moved to the sub cache from the main cache.

11. A method for operating a data storage device including a nonvolatile memory device and a controller which controls a read retry operation of the nonvolatile memory device, the method comprising:
performing a first read retry voltage setting operation;
performing a first read retry control operation;
performing a second read retry voltage setting operation after an internal operation time of the nonvolatile memory device according to the first read retry control operation passes; and
performing a second read retry control operation.

12. The method according to claim 11, further comprising performing a first data output control operation of controlling the nonvolatile memory device to output data sensed according to the first read retry control operation after an internal operation time of the nonvolatile memory device according to the second read retry control operation passes.

13. The method according to claim 12, further comprising omitting a second data output control operation of controlling the nonvolatile memory device to output data sensed according to the second read retry control operation, in the case where the error of the data sensed according to the first read retry control operation is correctable.

14. The method according to claim 12 wherein the first data output control operation comprises an operation of providing a read control signal or a data strobe signal to the nonvolatile memory device.

15. The method according to claim 12, further comprising performs a second data output control operation of controlling the nonvolatile memory device to output data sensed according to the second read retry control operation, in the case where an error of the data sensed according to the first read retry control operation is uncorrectable.

16. A data storage device comprising:
a nonvolatile memory device; and
a controller suitable for control the nonvolatile memory device to perform a read retry caching operation according to various levels of read retry voltages,
wherein during the read retry caching operation the controller controls the nonvolatile memory device to cache a first data sensed according to a first read retry voltage while sensing a second data according to a second read retry voltage.

17. The data storage device according to claim 16,
wherein the controller further controls the nonvolatile memory device to cache the sensed second data, and
wherein the controller further controls the nonvolatile memory device to provide the cached first data to the controller after the nonvolatile memory device caches the sensed second data.

18. The data storage device according to claim 17, wherein the controller further controls the nonvolatile memory device to sense and cache a third data according to a third read retry voltage after the nonvolatile memory device to provide the cached first data to the is controller.

19. The data storage device according to claim 18, wherein the controller further controls the nonvolatile memory device to provide the cached second data to the controller when an error of the provided first data cannot be corrected.

20. The data storage device according to claim 19, wherein the controller further repeats the read retry caching operation by changing levels of the first to third read retry voltages until an error of the provided first data can be corrected.
